(19) United States
(12) Patent Application Publication
(10) Pub. No.: US 2009/0008724 A1
(43) Pub. Date: Jan. 8, 2009

(54) SEMICONDUCTOR DEVICE AND METHOD OF MANUFACTURING THE SAME

(75) Inventors: Yasuyoshi MISHIMA, Ebina (JP); Masaomi YAMAGUCHI, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: Fujitsu Limited, Kawasaki-shi (JP)

(21) Appl. No.: 12/187,050

(22) Filed: Aug. 6, 2008

Related U.S. Application Data
(63) Continuation of application No. PCT/JP2006/302067, filed on Feb. 7, 2007.

(51) Int. Cl. H01L 21/28; H01L 29/423

(52) U.S. Cl. 257/410; 438/591; 257/E29.132; 257/E21.192

(57) ABSTRACT

The semiconductor device according to the present invention comprises a gate insulating film 16 formed on a silicon substrate 10 and including a silicon oxide film 12 and a Hf-based high dielectric constant insulating film 14 doped with Al; a gate electrode 18 of a polysilicon film formed on the gate insulating film 16; and a sidewall insulating film 20 formed on the side walls of the gate electrode 18 and the Hf-based high dielectric constant insulating film 14, and the maximum value of the depth-wise concentration distribution of the Al doped in the Hf-based high dielectric constant insulating film 14 is 1×10²¹-4×10²¹ atoms/cm³.

### CROSS REFERENCE TO RELATED APPLICATIONS

This application is a Continuation of International Application No. PCT/JP2006/302067, with an international filing date of Feb. 7, 2006, which designating the United States of America, the entire contents of which are incorporated herein by reference.

### TECHNICAL FIELD

The present invention relates to a semiconductor device and a method of manufacturing the semiconductor device.

### BACKGROUND

As the insulating film of the gate insulating film, the tunnel insulating film, etc. of the MOS structure, the insulating film of a silicon oxide film has been so far used. However, as the semiconductor devices are increasingly downsized, the gate insulating film and the tunnel insulating film are increasingly thinned. Consequently, difficulties of the increase of the gate leak current due to the tunnel current, etc. have become conspicuous. To solve these difficulties, studies of using insulating films of higher dielectric constants than silicon oxide film (hereinafter called high dielectric constant insulating film in the specification of the present application) in the gate insulating film, etc. and increasing the physical film thickness of the gate insulating film, etc. are being made.

As such high dielectric constant insulating film, for example, hafnium (Hf)-based high dielectric constant insulating films of oxides, nitrides and oxide nitrides, which contain Hf, are prospective.

However, with a gate electrode of polysilicon being formed on a Hf-based high dielectric constant insulating film, the threshold voltage of the transistor is pinned at a certain value by the reaction between the Hf-based high dielectric constant insulating film and the silicon, which is the material of the gate electrode. The pinning of the threshold voltage is an obstacle to forming the CMOS. Such pinning of the threshold voltage, i.e., the Fermi level pinning is a problem to be solved in using the Hf-based high dielectric constant insulating film in the gate insulating film.

To solve such problem, a trial of forming a gate electrode in a metal gate of metal is made. However, it is not easy to incorporate the step of forming a metal film in the line of the usual semiconductor process. This is because when the metal material is mixed in the semiconductors in the rest region other than the prescribed region, the metal causes various defect levels.

Then, as a new trial, the top of the gate electrode of polysilicon is covered by a metal film of Ni and Co, or others to form a silicide layer by thermal processing, and the silicide layer is grown to the interface with the gate insulating film.

However, in any of the trials, a defect is that the threshold voltage cannot be controlled in a wide range, and the Fermi level pinning, which is a problem in using the gate electrode of polysilicon, cannot be solved.

It is reported in 2005 VLSI Symp., p. 70 that Al is introduced by 7.5-44 at % homogeneously into HfO₂ film to thereby change the threshold voltage of PMOS transistors. However, the change amount is insufficient.

### SUMMARY

According to one aspect of an embodiment, there is provided a semiconductor device comprising: a gate insulating film formed over a semiconductor substrate and including an Hf-based insulating film doped with at least one kind of metal selected out of a group of Al, Cr, Ti and Y; and a gate electrode formed over the gate insulating film, a depth-wise concentration distribution of the metal doped in the Hf-based high dielectric constant insulating film having the maximum value of 1×10²¹ atoms/cm³-4×10²¹ atoms/cm³.

According to another aspect of an embodiment, there is provided a method of manufacturing a semiconductor device comprising: forming an Hf-based insulating film over a semiconductor substrate; doping at least one kind of metal selected out of a group of Al, Cr, Ti and Y in the Hf-based insulating film so that the maximum value of a depth wide concentration distribution of the metal doped in the Hf-based insulating film is 1×10²¹ atoms/cm³-4×10²¹ atoms/cm³; and forming a gate electrode over the Hf-based insulating film.

### BRIEF DESCRIPTION OF THE DRAWINGS

FIG. 1 is a sectional view showing the structure of the semiconductor device according to a first embodiment of the present invention.

FIG. 2 is a graph showing the capacitance-voltage characteristics of the MOS transistor using the Hf-based high dielectric constant insulating film in the gate insulating film.

FIG. 3 is a graph showing the relationship between the Al doping period of time and the change of the threshold voltage for the PMOS transistor.

FIG. 4 is a graph showing the relationship between the Al doping period of time and the change of the threshold voltage for the NMOS transistor.

FIG. 5 is a graph of the depth-wise concentration distribution of Al doped in the Hf-based high dielectric constant insulating film of the semiconductor device according to the first embodiment of the present invention.

FIGS. 6A-6D and 7A-7D are sectional views showing the method of manufacturing the semiconductor device according to the first embodiment of the present invention.

FIG. 8 is a sectional view showing the structure of the semiconductor device according to a second embodiment of the present invention.

FIGS. 9A-9D and 10A-10D are sectional views showing the method of manufacturing the semiconductor device according to the second embodiment of the present invention.

### DETAILED DESCRIPTION OF THE EMBODIMENTS

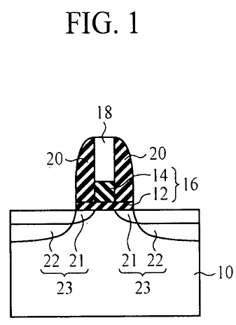

The semiconductor device and the method of manufacturing the same according to a first embodiment of the present invention will be explained with reference to FIGS. 1 to 7D.

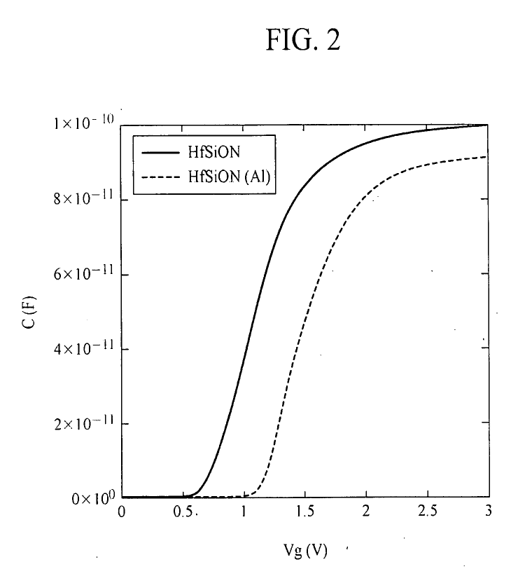

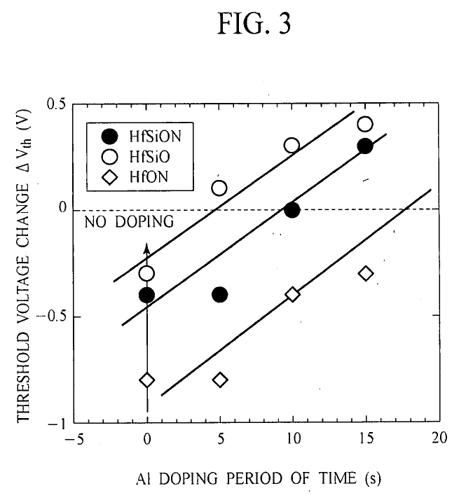

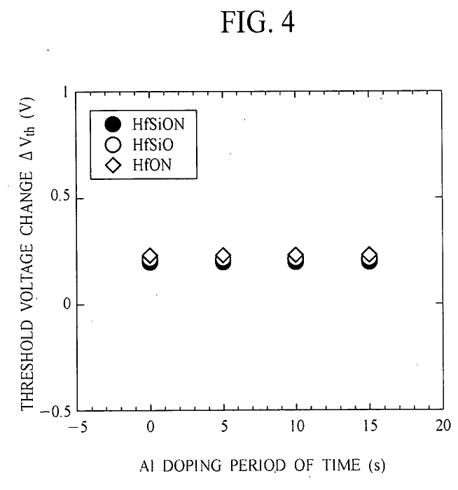

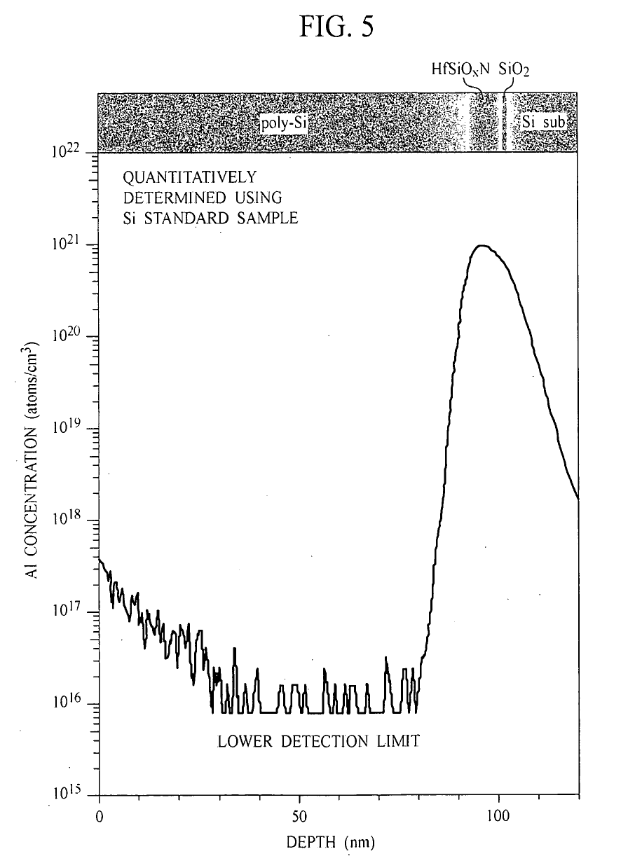

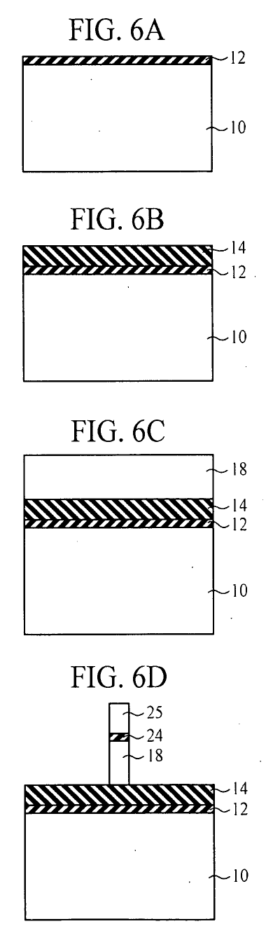

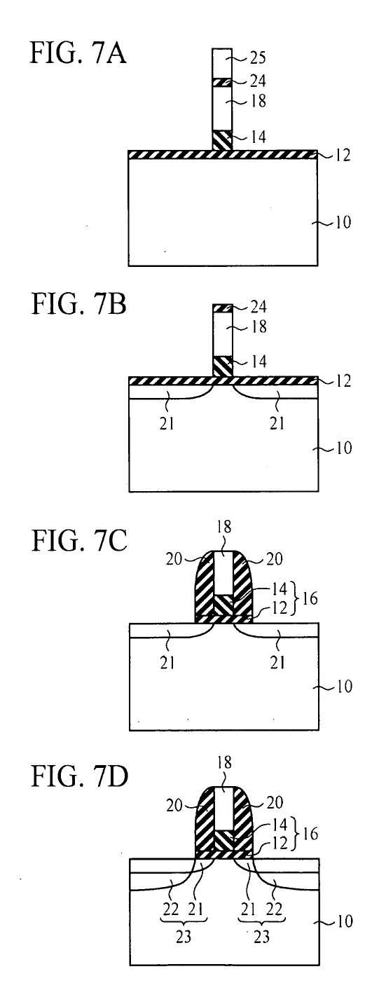

FIG. 1 is a sectional view showing the structure of the semiconductor device according to the present embodiment. FIG. 2 is a graph showing the capacitance-voltage characteristics of the MOS transistor using the Hf-based high dielectric constant insulating film in the gate insulating film. FIG. 3 is a graph showing the relationship between the Al doping period of time and the change of the threshold voltage for the PMOS transistor. FIG. 4 is a graph showing the relationship between the Al doping period of time and the change of the threshold voltage for the NMOS transistor. FIG. 5 is a graph of the depth-wise concentration distribution of Al doped in the Hf-based high dielectric constant insulating film of the semiconductor device according to the present embodiment. FIGS. 6A-6D and 7A-7D are sectional views showing the method of manufacturing the semiconductor device according to the present embodiment.

First, the structure of the semiconductor device according to the present embodiment will be explained with reference to FIG. 1.

On a silicon substrate 10, a gate insulating film of a silicon oxide film 12 and a Hf-based high dielectric constant insulating film 14 laid the latter on the former is formed. The Hf high dielectric constant insulating film 14 is, e.g., a HfSiON film, a HfSiO film, a HfON film or another. As will be described later, the Hf high dielectric constant insulating film 14 is doped with a trace of aluminum (Al). The maximum value, i.e., the maximum concentration peak of the depth-wise concentration distribution of the Al doped in the Hf-based high dielectric constant insulating film 14 is, e.g., 1×10²¹-4×10²¹ atoms/cm³. In the specification of the present application, the “high dielectric constant” of the high dielectric constant insulating film means having a higher dielectric constant than silicon oxide. Especially, the Hf-based high dielectric constant insulating film means an insulating film of an oxide, a nitride or an oxynitride, which contains Hf and whose dielectric constant is higher than silicon oxide film.

On the gate insulating film 16, a gate electrode 18 of a polysilicon film is formed. No Al layer is formed between the gate electrode 18 and the Hf-based high dielectric constant insulating film 14.

On the side walls of the gate electrode 18 and the Hf-based high dielectric constant insulating film 14, a sidewall insulating film 20 is formed.

In the silicon substrate 10 on both sides of the gate electrode 18, shallow impurity-diffused regions 21 with an impurity implanted in a low concentration is formed by the self-alignment with the gate electrode 18. Furthermore, by the self-alignment with the sidewall insulating film 20 and the gate electrode 18, deep impurity-diffused regions 22 with an impurity implanted in a high concentration are formed. These impurity-diffused regions 21, 22 form source/drain regions 23 of the Lightly Doped Drain (LDD) structure.

Thus, a MOS transistor comprising the gate electrode 18 and the source/drain regions 23, with the gate insulating film 16 including the Hf-based high dielectric constant insulating film 14 is formed.

The semiconductor device according to the present embodiment is characterized mainly in that the Hf-based high dielectric insulating film 14 used in the gate insulating film 16 is doped with a trace of Al.

So far, as the means for solving the Fermi level pinning in the Hf-based high dielectric constant film used in the gate insulating film, various methods have been studied. As the model of the cause for the Fermi level pinning, various models have been proposed.

The inventors of the present application made earnest studies of means of solving the Fermi level pinning, based on the model, as the model of the cause for the Fermi level pinning, that oxygen in the Hf-based high dielectric constant insulating film goes into the gate electrode of polysilicon film, and the electrons remaining the Hf-based high dielectric constant insulating film form a level. Resultantly, the inventors have concluded that a processing for suppressing the transit of oxygen between the gate electrode of polysilicon film and the Hf-based high dielectric constant insulating film could solve the Fermi level pinning.

In the semiconductor device according to the present embodiment, as described above, the Hf-based high dielectric constant insulating film 14 used in the gate insulating film 16 is doped with a trace of Al of, e.g., 1×10²¹-4×10²¹ atoms/cm³ which is the maximum value of the depth-wise distribution. The Al doped in the Hf-based high dielectric constant insulating film 14 functions as the fixing material for fixing the oxygen to thereby prevent the transit of the oxygen from the Hf-based high dielectric constant insulating film 14 to the gate electrode 18 of the polysilicon film. The transit of the oxygen from the Hf-based high dielectric constant insulating film 14 to the silicon substrate 10 can be also prevented. Thus, the Fermi level pinning can be solved and the threshold voltage can be controlled in a wide range.

FIG. 2 is a graph of the capacity-voltage characteristics measured on a MOS transistor (diode) having the Hf-based high dielectric constant insulating film doped with Al and a MOS transistor (diode) having the Hf-based high dielectric constant insulating film not doped with Al. On the horizontal axis of the graph, the gate voltage V_{g} is taken, and on the vertical axis, the capacity C between the gate electrode and the silicon substrate is taken.

In the figure, the graph of the solid line is of the MOS transistor using a HfSiON film not doped with Al as the Hf-based high dielectric constant insulating film and including the gate electrode of the polysilicon film on the HfSiON film. In the figure, the graph of the broken line is of the MOS transistor using a HfSiON film doped with Al with the maximum concentration peak of 1×10²¹ atoms/cm³ and including the gate electrode of the polysilicon film on the HfSiON film. In each case, as the gate electrode, p⁺ type one formed of the polysilicon film with boron (B) as an impurity ion-implanted and activated by thermal processing is used.

As shown in FIG. 2, it is found based on the change of the capacity-voltage characteristics due to the presence and absence of the Al doping that doping of a trace of Al in the Hf-based high dielectric constant insulating film that the threshold voltage is largely changed by doping a trace of Al in the Hf-based high dielectric constant film.

FIG. 3 is a graph plotting changes ΔVₜₕ of the threshold voltage for the Al doping periods of time measured on PMOS transistors. On the horizontal axis of the graph, the Al doping period of time of doping the Hf-based high dielectric constant insulating film used in the gate insulating film is taken, and the change ΔVₜₕ of the threshold voltage is taken on the vertical axis. The PMOS transistors use the Hf-based high dielectric constant insulating film in the gate insulating film and include a p⁺ type gate electrode of a polysilicon film. Here, the change ΔVₜₕ of the threshold voltage means a voltage of a shift from a threshold voltage estimated based on a work function of an impurity concentration of the silicon substrate and the p/n polysilicon gate of a transistor using the usual silicon oxide film in the gate insulating film. The plots of the mark indicate the case that the Hf-based high dielectric constant insulating film is a HfSiON film, the plots of the ◯ mark indicate the case that the Hf-based high dielectric constant film is a HfSiO film, and the plots of the ⋄ mark indicate the case that the Hf-based high dielectric constant insulating film is a HfON film.

As evident in the graph of FIG. 3, it is found that that, in the PMOS transistor, for the Hf-based high dielectric constant insulating films of the HfSiON film, the HfSiO film and the HfON film, the Al doping period of time, i.e., Al doping amount is changed, whereby the threshold voltage Vth can be controlled in a wide range.

On the other hand, FIG. 4 is a graph plotting the changes ΔVₜₕ of the threshold voltage for the Al doping periods of time measured on NMOS transistors. On the horizontal axis of the graph, the Al doping period of time of doping the Hf-based high dielectric constant insulating film used in the gate insulating film is taken, and the change ΔVₜₕ of the threshold voltage is taken on the vertical axis. The NMOS transistors use the Hf-based high dielectric constant insulating film in the insulating film and include the n⁺ type gate electrode of a polysilicon film. The plots of the mark indicate the case that the Hf-based high dielectric constant film is a HfSiON film, and the plots of the ◯ mark indicate the case that the Hf-based high dielectric constant insulating film is a HfSiO film, and the plots of the ⋄ mark indicate the case that the Hf-based high dielectric constant insulating film is a HfON film.

As evident in the graph of FIG. 4, in the NMOS transistor, for the Hf-based high dielectric constant insulating films of the HfSiON film, the HfSiO film and the HfON film, there is no substantial change ΔVₜₕ even with the Al doping period of time, i.e., the Al doping amount changed. This result is different from the phenomenon that a fixed charge is generated in the hafnium aluminate-based high dielectric constant insulating film to change the threshold voltage. Based on this result, it is found that a trace of Al is doped in the Hf-based high dielectric constant insulating film, whereby the pinning of the threshold voltage of the transistor using the Hf-based high dielectric constant insulating film in the gate insulating film and a polysilicon film as the gate electrode is sufficiently suppressed.

As described above, in the semiconductor device according to the present embodiment, a trace of Al is doped in the Hf-based high dielectric constant insulating film 14 used in the gate insulating film 16, whereby the pinning of the threshold voltage of the transistor can be sufficiently suppressed, and the threshold voltage can be controlled in a wide range. The doping of a trace of Al neither deteriorates the characteristics of the Hf-based high dielectric constant insulating film 14 as the high dielectric constant film.

FIG. 5 is a graph of one example of the depth-wise concentration distribution of Al doped in the Hf-based high dielectric constant insulating film. The depth-wise concentration distribution was measured by the secondary ion mass spectrometry (SIMS). On the horizontal axis of the graph, the depth from the surface of polysilicon film forming the gate electrode is taken, and the Al concentration is taken on the vertical axis. The sample the SIMS was made is a PMOS transistor of a 0.8 eV threshold voltage including a HfSiON film as the Hf-based high dielectric constant insulating film.

As seen in the graph of FIG. 5, the Al doped in the HfSiON film has the depth-wise concentration distribution, and the maximum concentration peak is about 1×10²¹ atoms/cm³. It is also seen that the HfSiON film is doped with a trace of Al, and no hafnium aluminate film is formed.

Here, in the example of FIG. 5, the Al doping period of time is 5 s, and the Al depth-wise maximum concentration peak is 2×10²¹ atoms/cm³ for 20 s and 3×10²¹ atoms/cm³ for 15 s.

Preferably, the concentration and distribution of Al to be doped in the Hf-based high dielectric constant insulating film 14 are suitably adjusted. For example, when the Hf-based high dielectric constant insulating film 14 is HfSiON, the hysteresis of the transistor characteristics increases when the maximum concentration peak of the doped Al is above 3×10²¹ atoms/cm³. Accordingly, it is preferable that the maximum concentration peak of the Al doped in the Hf-based high dielectric constant insulating film 14 is below 3×10²¹ atoms/cm³ including 3×10²¹ atoms/cm³. When the Hf-based high dielectric constant insulating film 14 is HfSiON, it is difficult to sufficiently suppress the pinning of the threshold voltage when the maximum concentration peak of the doped Al is below 1×10²¹ atoms/cm³. Accordingly, it is preferable that the maximum concentration peak of the Al doped in the Hf-based high dielectric constant insulating film 14 is above 1×10²¹ atoms/cm³ including 1×10²¹ atoms/cm³. When the Hf-based high dielectric constant insulating film 14 is HfSiO and HfON, Al should be more heavily doped than when the Hf-based high dielectric constant insulating film 14 is HfSiON. Even in this case, when Al is doped up to 4×10²¹ atoms/cm³, the threshold voltage can be controlled in a wide range.

Next, the method of manufacturing the semiconductor device according to the present embodiment will be explained with reference to FIGS. 6A-6D and 7A-7D.

First, the silicon substrate 10 is subjected to a prescribed cleaning processing.

Then, the surface of the silicon substrate 10 is oxidized by the processing using, e.g., a chemical liquid mixing hydrochloric acid and hydrogen peroxide water to form a silicon oxide film 12 of, e.g., below a 1 nm-thickness including a 1 nm-thickness on the surface of the silicon substrate 10 (see FIG. 6A).

Next, on the silicon oxide film 12, the Hf-based high dielectric constant insulating film 14 of, e.g., a 3,5 nm-thickness HfSiON film is formed by, e.g., CVD method (see FIG. 6B). The film forming conditions for forming the Hf-based high dielectric insulating film 14 of the HfSiON film are, e.g., tetrakis(dimethylamino)hafnium (TDMAH; Hf(N(CH₃)₂)₄), tris(dimethylamino)silane (TDMAS; SiH(N(CH₃)₂)₃) and nitrogen monoxide as the raw material, and the substrate temperature of 600° C.

Then, the surface of the Hf-based high dielectric constant insulating film 14 is exposed to the gas of an organic aluminum compound to dope a trace of Al into the Hf-based high dielectric constant insulating film 14. As the organic aluminum compound, trimethylaluminum (TMA; Al(CH₃)₃) is used, and the TMA gas is introduced into the chamber housing the substrate by bubbling using nitrogen gas. At this time, the substrate temperature is, e.g., 500-700° C., specifically 600° C. The period of time of the exposure to the TMA gas is, e.g., 5-20 seconds.

In the step of exposing the surface of said Hf-based high dielectric constant insulating film 14 to the gas of an organic aluminum compound, no Al layer is formed on the Hf-based high dielectric constant insulating film 14.

Between the Hf-based high dielectric constant insulating film 14 and the silicon substrate 10, the silicon oxide film 12 is formed. This silicon oxide film 12 prevents the diffusion of the Al into the silicon substrate 10 to be the channel.

Then, thermal processing is made in, e.g., a nitrogen atmosphere to thereby densify the Hf-based high dielectric constant insulating film 14. The temperature of the thermal processing is, e.g., 700-1050° C., specifically, 780° C.

Then, on the Hf-based high dielectric constant insulating film 14, a 10 nm-thickness polysilicon film 18, for example, is formed by, e.g., CVD method (see FIG. 6C). The substrate temperature at this time is, e.g., 600° C.

Then, on the polysilicon film 18, a 10 nm-thickness silicon oxide film 24, for example, is formed. The silicon oxide film 24 is used as the hard mask for forming the gate electrode 18 by etching.

Next, a photoresist film 25 is formed on the silicon oxide film 24, and then by photolithography, a photoresist film 25 is left in the region where the gate electrode is to be formed.

Next, with the photoresist film 25 as the mask, the silicon oxide film 24 is dry-etched to pattern the silicon oxide film 24 to be used as the hard mask.

Next, with the photoresist film 25 and the silicon oxide film 24 as the mask, the polysilicon film 18 is dry-etched to form the gate electrode 18 of the polysilicon film (se FIG. 6D).

Next, with the photoresist film 25 and the silicon oxide film 24 as the mask, the Hf-based high dielectric constant insulating film 14 is dry-etched to thereby remove the Hf-based high dielectric constant insulating film 14 exposed on both sides of the gate electrode 18 (see FIG. 7A).

Then, the photoresist film 25 left on the silicon oxide film 24 is removed. The silicon oxide film 24 used as the mask is to be removed in a later etching step.

Next, with the gate electrode 18 as the mask, ion implantation is made to form in the silicon substrate 10 by self-alignment with the gate electrode 18, the shallow impurity diffused regions 21 lightly doped with an impurity (see FIG. 7B). By this ion implantation, the impurity is implanted also in the gate electrode 18.

Next, a silicon oxide film, for example, is formed on the entire surface, and then the silicon oxide film is anisotropically etched. Thus, on the side walls of the gate electrode 18 and the Hf-based high dielectric constant insulating film 14, the sidewall insulating film 20 of the silicon oxide film is formed (see FIG. 7C).

Next, with the sidewall insulating film 20 and the gate electrode 18 as the mask, ion implantation is made to form the deep impurity diffused regions 22 heavily doped with an impurity by the self-alignment with the sidewall insulating film 20 and the gate electrode 18. By this ion implantation, the impurity is implanted also in the gate electrode 18.

Thus, the source/drain regions 23 of the LDD structure are formed of the impurity diffused regions 21, 22 (see FIG. 7D).

Next, prescribed thermal processing is made to activate the impurities implanted by the ion implantation.

Thus, the semiconductor device according to the present embodiment shown in FIG. 1 is manufactured.

As described above, according to the present embodiment, the surface of the Hf-based high dielectric constant insulating film 14 is exposed to the gas of an organic aluminum compound to dope a trace of Al in the Hf-based high dielectric constant insulating film 14 to be used in the gate insulating film 16, whereby the pinning of the threshold voltage of the transistor can be sufficiently suppressed, and the threshold voltage can be controlled in a wide range.

The method of manufacturing the semiconductor device according to a modification of the present embodiment will be explained.

The method of manufacturing the semiconductor device according to the present modification is different from the method of manufacturing the semiconductor device described above in that the thermal processing for densifying the Hf-based high dielectric constant insulating film 14 is made before the step of doping a trace of Al in the Hf-based high dielectric constant insulating film 14. The method of manufacturing the semiconductor device according to the present modification will be explained below.

First, in the same way as in the method of manufacturing the semiconductor device described above shown in FIGS. 6A and 6B, the silicon oxide film 12 and the Hf-based high dielectric constant insulating film 14 are formed on the silicon substrate 10.

Next, thermal processing is made in, e.g., a nitrogen atmosphere to densify the Hf-based high dielectric constant insulating film 14. The temperature of the thermal processing is, e.g., 700-1050° C., specifically 780° C.

Then, as in the above, the surface of the Hf-based high dielectric constant insulating film 14 is exposed to the gas of an organic aluminum compound, e.g., TMA to thereby dope a trace of Al in the Hf-based high dielectric constant insulating film 14.

Then, on the Hf-based high dielectric constant insulating film 14, the polysilicon film 18 is formed by, e.g., CVD method.

The steps following the formation of the polysilicon film 18 are the same as those of the method of manufacturing the semiconductor device described above shown in FIGS. 6D to 7D.

As in the present modification, the thermal processing for densifying the Hf-based high dielectric constant insulating film 14 may be made before the step of doping a trace of Al in the Hf-based high dielectric constant insulating film 14.

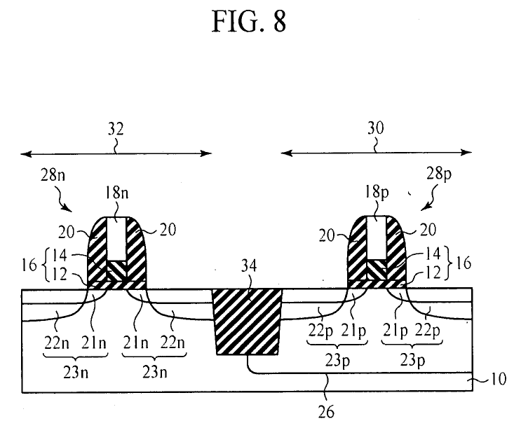

The semiconductor device and the method of manufacturing the same according to a second embodiment of the present invention will be explained with reference to FIGS. 8 to 10D. The same members of the present embodiment as those of the semiconductor device and the method of manufacturing the same according to the first embodiment are represented by the same reference numbers not to repeat or to simplify their explanation.

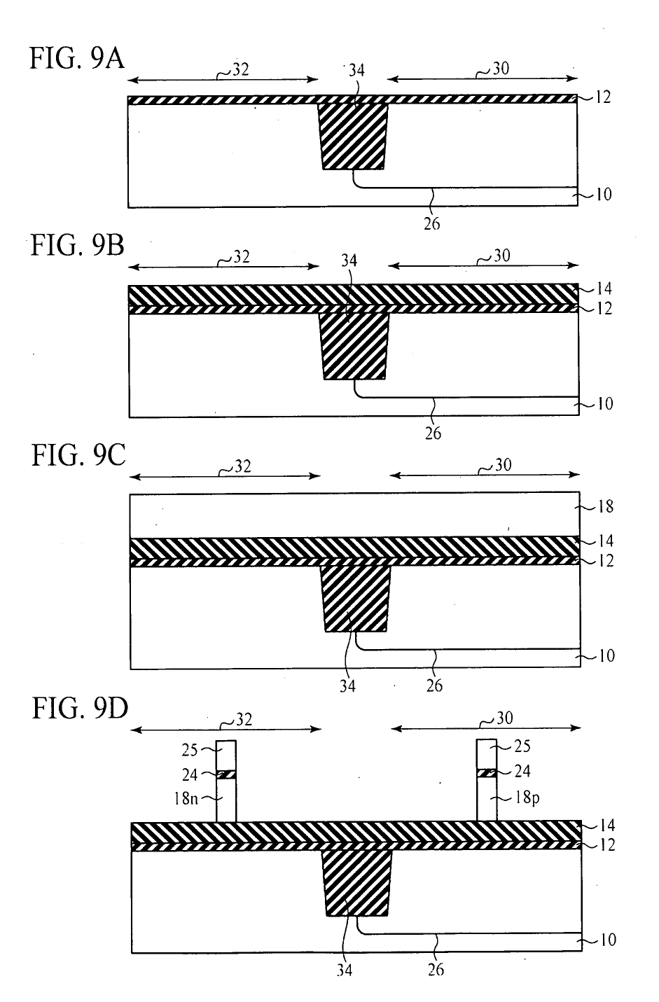

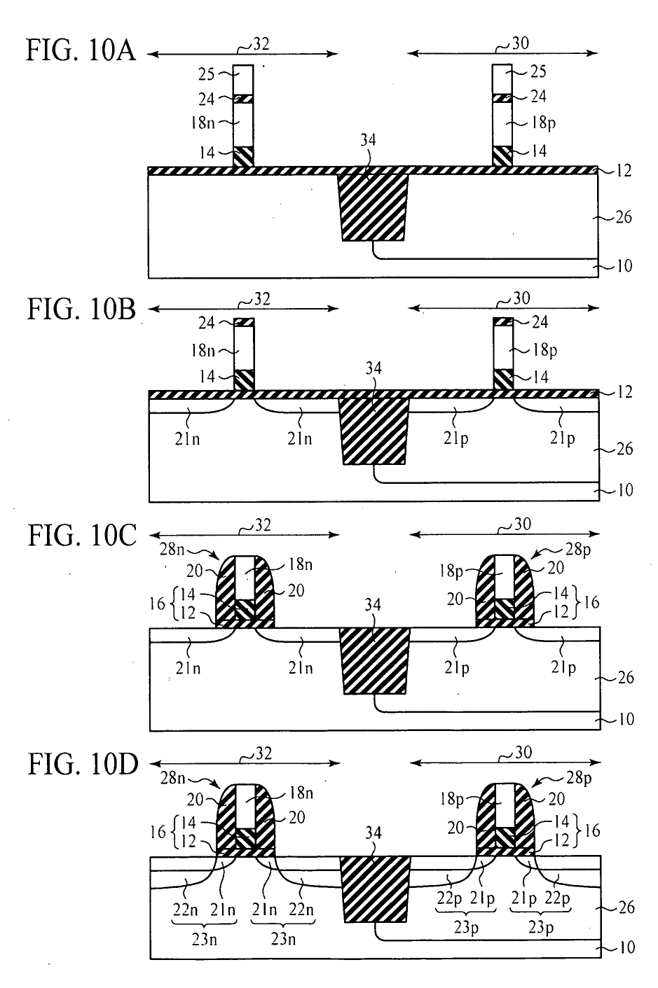

FIG. 8 is a sectional view showing the structure of the semiconductor device according to the present embodiment, and FIGS. 9A-9D and 10A-10D are sectional views showing the method of manufacturing the semiconductor device according to the present embodiment.

First, the structure of the semiconductor device according to the present embodiment will be explained with reference to FIG. 8.

The semiconductor device according to the present embodiment has a CMOS structure including a PMOS transistor and an NMOS transistor using the Hf-based high dielectric constant insulating film 14 doped with a trace of Al in the gate insulating film 16, as in the semiconductor device according to the first embodiment.

As illustrated, an n type well 26 is formed in a p type silicon substrate 10.

In the silicon substrate 10 with the well 26 formed in, a device isolating film 34 is formed, which defines a PMOS transistor region 30 where a PMOS transistor 18p is to be formed and an NMOS transistor region 32 where an NMOS transistor 28n is to be formed.

On the silicon substrate 10 in the PMOS transistor region 30, a gate insulating film 16 of a silicon oxide film 12 and a Hf-based high dielectric constant insulating film 14 laid the latter on the former is formed. The Hf-based high dielectric insulating film 14 is, e.g., a HfSiON film, a HfSiO film, a HfON film or another. The Hf-based high dielectric constant insulating film 14 is doped with a trace of Al. The maximum concentration peak of the Al doped in the Hf-based high dielectric constant insulating film 14 is, e.g., 1×10²¹-4×10²¹ atoms/cm³.

On the gate insulating film 16, a gate electrode 18p of a polysilicon film is formed. No Al layer is formed between the gate electrode 18p and the Hf-based high dielectric constant insulating film 14.

On the side walls of the gate electrode 18p and the Hf-based high dielectric constant insulating film 14, a sidewall insulating film 20 is formed.

In the silicon substrate 10 on both sides of the gate electrode 18p, shallow impurity diffused regions 21p lightly doped with an impurity is formed by self-alignment with the gate electrode 18p. Furthermore, by self-alignment with the sidewall insulating film 20 and the gate electrode 18p, deep impurity diffused regions 22 heavily doped with an impurity are formed. The impurity diffused regions 21p, 22p form source/drain regions 23p of the LDD structure.

Thus, in the PMOS transistor region 30, the PMOS transistor 28p comprising the gate electrode 18p and the source/drain regions 23p, with the gate insulating film 16 including the Hf-based high dielectric constant insulating film 14 is formed.

On the silicon substrate 20 in the NMOS transistor region 32, the gate insulating film 16 of the silicon oxide film 12 and the Hf-based high dielectric constant insulating film 14 laid the latter on the former is formed. The Hf-based high dielectric constant insulating film 14 is, e.g., a HfSiON film, a HfSiO film, a HfON film or another. The Hf-based high dielectric constant insulating film 14 is doped with a trace of Al. The maximum concentration peak of the Al doped in the Hf-based high dielectric constant insulating film 14 is, e.g., 1×10²¹-4×10²¹ atoms/cm³.

On the gate insulating film 16, a gate electrode 18n of a polysilicon film is formed. No Al layer is formed between the gate electrode 18n and the Hf-based high dielectric constant insulating film 14.

A sidewall insulating film 20 is formed on the side walls of the gate electrode 18n and the Hf-based high dielectric constant insulating film 14.

In the silicon substrate 10 on both sides of the gate electrode 18n, shallow impurity diffused regions 21n lightly doped with an impurity are formed by self-alignment with the gate electrode 18n. Furthermore, by self-alignment with the sidewall insulating film 20 and the gate electrode 18n, deep impurity diffused regions 22n heavily doped with an impurity are formed. The impurity diffused regions 21n, 22n form source/drain regions 23n of the LDD structure.

Thus, in the NMOS transistor region 32, the NMOS transistor 28n comprising the gate electrode 18n and the source/drain regions 23n, with the gate insulating film 16 including the Hf-based high dielectric constant insulating film 14 is formed.

The semiconductor device according to the present embodiment is characterized mainly in that the PMOS transistor 28p and the NMOS transistor 28n forming the CMOS structure respectively include the Hf-based high dielectric constant insulating film 14 included in the gate insulating film 16, which is doped with a trace of Al, as in the first embodiment.

This makes it possible to form the CMOS structure of the PMOS transistor 28p and the NMOS transistor 28n the pinning of whose threshold voltages is sufficiently suppressed and whose threshold voltages can be controlled in wide ranges. Accordingly, the performance of the semiconductor device of the CMOS structure can be improved.

Then, the method of manufacturing the semiconductor device according to the present embodiment will be explained with reference to FIGS. 9A-9D and 10A-10D.

First, in the p type silicon substrate 10, the n type well 26 is formed by, e.g., ion implantation.

Next, in the silicon substrate 10, the device isolating film 34 of a silicon oxide film is formed by, e.g., the usual STI method to define the PMOS transistor region 30 and the NMOS transistor region 32.

Then, the surface of the silicon substrate 10 is oxidized by the processing using a chemical liquid mixing, e.g., hydrochloric acid and hydrogen peroxide water to form the silicon oxide film 12 of, e.g., below a 1 nm-thickness including a 1 nm-thickness on the surface of the silicon substrate 10 (see FIG. 9A).

Next, on the silicon oxide film 12, the Hf-based high dielectric constant insulating film 14 of, e.g., a 3.5-nm thickness HfSiON film is formed by, e.g., CVD method (see FIG. 9B). The film forming conditions for forming the Hf-based high dielectric constant insulating film 14 of a HfSiON film are, e.g., TDMAH, TDMAS and NO as the raw material gas and the substrate temperature of 600° C.

Next, the surface of the Hf-based high dielectric constant insulating film 14 is exposed to the gas of an organic aluminum compound to thereby dope a trace of Al in the Hf-based high dielectric constant insulating film 14. As the organic aluminum compound is, TMA, for example, is used, and by bubbling using nitrogen gas, the gas of TMA is introduced into the chamber housing the substrate. At this time, the substrate temperature is, e.g., 600° C. The period of time of exposing the substrate to the TMA gas is, e.g., 5-20 seconds.

Then, thermal processing is made in, e.g., a nitrogen atmosphere to densify the Hf-based high dielectric insulating film 14. The temperature of the thermal processing is, e.g., 700-1050° C., specifically 780° C.

Next, on the Hf-based high dielectric constant insulating film 14, a 120 nm-thickness polysilicon film 18 is formed by, e.g., CVD method (see FIG. 9C). The substrate temperature at this time is, e.g., 600° C.

Next, on the polysilicon film 18, a 10 nm-thickness silicon oxide film 24, for example, is formed. The silicon oxide film 24 is used as the hard mask for forming the gate electrodes 18p, 18n by etching.

Then, a photoresist film 25 is formed on the silicon oxide film 24, and then by photolithography, the photoresist film 25 is left in the regions where the gate electrodes are to be formed in.

Next, with the photoresist film 25 as the mask, the silicon oxide film 24 is dry-etched to thereby pattern the silicon oxide film 24 to be used as the hard mask.

Next, with the photoresist film 25 and the silicon oxide film 24 as the mask, the polysilicon film 18 is dry-etched to thereby form the gate electrodes 18p, 18n of the polysilicon film (see FIG. 9D).

Next, with the photoresist film 25 and the silicon oxide film 24 as the mask, the Hf-based high dielectric constant insulating film 14 is dry-etched to thereby remove the Hf-based high dielectric constant insulating film 14 exposed on both sides of the gate electrodes 18p, 18n (see FIG. 10A).

Next, the photoresist film 25 remaining on the silicon oxide film 24 is removed. The silicon oxide film 24 used as the mask is to be removed in a later etching step.

Then, by photolithography, a photoresist film (not illustrated) exposing the NMOS transistor region 32 and covering the rest region is formed. Next, with the photoresist film and the gate electrode 18n as the mask, an n type impurity, e.g., phosphorus (P) or others is ion-implanted in the silicon substrate 10 in the NMOS transistor region 32. Thus, in the silicon substrate 10 in the NMOS transistor region 32, by self-alignment with the gate electrode 18n, the shallow impurity diffused regions 21n lightly doped with the n type impurity are formed. By this ion implantation, the n type impurity is implanted also in the gate electrode 18n.

After the ion implantation was made in the NMOS transistor region 32, the photoresist film used as the mask is removed.

Next, by photolithography, a photoresist film (not illustrated) exposing the PMOS transistor region 30 and covering the rest region is formed. Then, with the photoresist film and the gate electrode 18p as the mask, in the silicon substrate 10 in the PMOS transistor region 30, a p type impurity, e.g., B or others is ion-implanted. Thus, in the silicon substrate 10 in the PMOS transistor region 30, the shallow impurity diffused regions 21p lightly doped with the p type impurity are formed by self alignment with the gate electrode 18p. By this ion implantation, the p type impurity is implanted also in the gate electrode 18p.

After the ion implantation in the PMOS transistor region 30, the photoresist film sued as the mask is removed.

Thus, in the NMOS transistor region 32 and the PMOS transistor region 30, the impurity diffused regions 21n, 21p are formed (see FIG. 10B).

Next, a silicon oxide film, for example, is formed on the entire surface and then is anisotropically etched. Thus, the sidewall insulating film 20 of the silicon oxide film is formed on the side walls of the gate electrodes 18p, 18n and the Hf-based high dielectric constant insulating film 14 (see FIG. 10C).

Next, by photolithography, a photoresist film (not illustrated) exposing the NMOS transistor region 32 and covering the rest region is formed. Then, with this photoresist film, the sidewall insulating film 20 and the gate electrode 18n as the mask, in the silicon substrate 10 in the NMOS transistor region 32, an n type impurity, e.g., P or others is ion-implanted. Thus, in the silicon substrate 10 in the NMOS transistor region 32, by self-alignment with the sidewall insulating film 20 and the gate electrode 19n, the deep impurity diffused regions 22n heavily doped with the n type impurity are formed. By this ion implantation, the n type impurity is implanted also in the gate electrode 18n.

After the ion implantation in the NMOS transistor region 32, the photoresist film used as the mask is removed.

Then, by photolithography, a photoresist film (not illustrated) exposing the PMOS transistor region 30 and covering the rest region is formed. Next, with this photoresist film, the sidewall insulating film 20 and the gate electrode 18p as the mask, in the silicon substrate 10 in the PMOS transistor region 30, a p type impurity, e.g., B or others is ion-implanted. Thus, in the silicon substrate 10 in the PMOS transistor region 30, by self-alignment with the sidewall insulating film 20 and the gate electrode 18p, the deep impurity diffused regions 22p heavily doped with the p type impurity are formed. By this ion implantation, the p type impurity is implanted also in the gate electrode 18p.

After the ion implantation in the PMOS transistor region 30, the photoresist film used as the mask is removed.

Thus, in the NMOS transistor region 32, the source/drain regions 23n of the LDD structure including the impurity diffused regions 21n, 22n are formed. In the PMOS transistor region 30, the source/drain regions 23p of the LDD structure including the impurity diffused regions 21p, 22p are formed (see FIG. 10D).

Next, prescribed thermal processing is made to activate the impurities implanted by the ion implantation.

Thus, the semiconductor device according to the present embodiment shown in FIG. 8 is manufactured.

As described above, according to the present embodiment, the surface of the Hf-based high dielectric constant insulating film 14 is exposed to the gas of an organic aluminum compound to thereby dope a trace of Al in the Hf-based high dielectric constant insulating film 14 used in the gate insulating film 16 of the PMOS transistor 28p and the NMOS transistor 28n forming the CMOS structure, whereby the PMOS transistor 28p and the NMOS transistor 28n, which can sufficiently suppress the pinning of the threshold voltage and can control the threshold voltage in a wide range, can form the CMOS structure. Accordingly, the semiconductor device of the CMOS structure can improve the performance.

The present invention is not limited to the above-described embodiments and can cover other various modifications.

For example, in the above-described embodiments, as the Hf-based high dielectric constant film 14, a HfSiON film, a HfSiO film or a HfON film can be used, but the Hf-based high dielectric constant insulating film 14 is not limited to them. As the Hf-based high dielectric constant insulating film 14, other than the above, high dielectric constant film of oxides, nitrides and oxide nitrides containing Hf, such as a HfO₂ film, a HfSiN film, etc., for example, can be used.

In the above-described embodiments, the gate electrode 18 of a polysilicon film is used, but the material of the gate electrode 18 is not essentially polysilicon. The gate electrode 18 can be formed of a conductive film other than polycrystal silicon, such as polycrystal silicon germanium (SiGe), silicide, gelicide or others. Gelicide means a compound of metal and germanium.

In the above-described embodiments, the Hf-based high dielectric constant insulating film 14 is doped with Al by exposing the surface of the Hf-based high dielectric constant insulating film 14 to the gas of TMA, but the organic aluminum compound for doping Al is not essentially TMA. The organic aluminum compound can be tritertiarybutylaluminum (TTBA) other than TMA.

In the above-described embodiments, Al is doped in the Hf-based high dielectric constant insulating film 14, but a metal to be doped in the Hf-based high dielectric constant insulating film 14 is not essentially Al. As a metal to be doped in the Hf-based high dielectric constant insulating film 14, other than Al, chrome (Cr), titanium (Ti), yttrium (Y) or others can be used. To dope Cr, T, Y or others can be doped by exposing the surface of the Hf-based high dielectric constant insulating film 14 to the gas of an organic metal compound containing the metal. The metal as well as Al is doped in the Hf-based high dielectric constant insulating film 14 so that the maximum concentration peak can be, e.g., 1×10²¹-4×10²¹ atoms/cm³, whereby the pinning of the threshold voltage can be sufficiently suppressed, and the threshold voltage can be controlled in a wide range.

### INDUSTRIAL APPLICABILITY

The semiconductor device and the method of manufacturing the same according to the present invention makes it possible that a transistor using the Hf-based high dielectric constant insulating film in the gate insulating film can sufficiently suppress the pinning of the threshold voltage and control the threshold voltage in a wide range. Accordingly, the semiconductor device and the method of manufacturing the same according to the present invention are very useful to improve the performance of the transistor using the Hf-based high dielectric constant insulating film in the gate insulating film.

What is claimed is:

1. A semiconductor device comprising:
a gate insulating film formed over a semiconductor substrate and including an Hf-based insulating film doped with at least one kind of metal selected out of a group of Al, Cr, Ti and Y; and
a gate electrode formed over the gate insulating film,
a depth-wise concentration distribution of the metal doped in the Hf-based insulating film having the maximum value of 1×10²¹ atoms/cm³-4×10²¹ atoms/cm³.

2. The semiconductor device according to claim 1, wherein
the gate electrode is formed of a conductive film containing Si.

3. The semiconductor device according to claim 2, wherein
the gate electrode includes a polycrystal silicon film, a polycrystal silicon germanium film or a silicide film.

4. The semiconductor device according to claim 1, wherein
the gate electrode includes a gelicide film.

5. A method of manufacturing a semiconductor device comprising:
forming an Hf-based insulating film over a semiconductor substrate;
doping at least one kind of metal selected out of a group of Al, Cr, Ti and Y in the Hf-based insulating film so that the maximum value of a depth wide concentration distribution of the metal doped in the Hf-based insulating film is 1×10²¹ atoms/cm³-4×10²¹ atoms/cm³; and
forming a gate electrode over the Hf-based insulating film.

6. The method of manufacturing a semiconductor device according to claim 5, wherein
in doping the metal in the Hf-based insulating film, a surface of the Hf-based insulating film is exposed to a gas of an organic metal compound containing the metal to thereby dope the metal in the Hf-based insulating film.

7. The method of manufacturing a semiconductor device according to claim 5, further comprising after doping the metal in the Hf-based insulating film and before forming the gate electrode,
making thermal processing densifying the Hf-based insulating film.

8. The method of manufacturing a semiconductor device according to claim 6, further comprising after doping the metal in the Hf-based insulating film and before forming the gate electrode,
making thermal processing densifying the Hf-based insulating film.

9. The method of manufacturing a semiconductor device according to claim 5, further comprising after forming the Hf-based insulating film and before doping the meal in the Hf-based insulating film,
making thermal processing densifying the Hf-based insulating film.

10. The method of manufacturing a semiconductor device according to claim 6, further comprising after forming the Hf-based insulating film and before doping the meal in the Hf-based insulating film,
making thermal processing densifying the Hf-based insulating film.
